(19) United States
(12) Patent Application Publication
(10) Pub. No.: US 2026/0073699 A1
(43) Pub. Date: Mar. 12, 2026

(54) SYSTEMS AND METHODS FOR SAFETY PROTOCOL AND ARCHITECTURAL DESIGN PLANNING USING VIDEO ANALYSIS

(71) Applicant: Flash Fire Inspector, LLC, Marietta, GA (US)

(72) Inventors: Simon Goodhead, Marietta, GA (US); David Mustard, Arvada, CO (US)

(73) Assignee: Flash Fire Inspector, LLC, Marietta, GA (US)

(21) Appl. No.: 18/883,651

(22) Filed: Sep. 12, 2024

(51) Int. Cl. G06V 20/52; G06F 30/13; G06V 10/74; G06V 40/10

(52) U.S. Cl. CPC G06V 20/53; G06F 30/13; G06V 10/761; G06V 40/10

(57) ABSTRACT

A system including a camera and a processor is disclosed. The camera is configured to capture a plurality of images of an area of interest in a geographical area. The processor is configured to execute an image processing algorithm on the images, and determine a plurality of parameters in real-time associated with the area of interest based on the images. The plurality of parameters may include a distance of each user, of a plurality of users, from adjacent users in the area of interest. The processor may further determine that the distance associated with at least one user, of the plurality of users, is less than a predefined threshold. The processor may additionally estimate, based on the images, a characteristic of relatability between the user and an adjacent user, and transmit the plurality of parameters and an information associated with the characteristic to an external device.

### FIELD

The present disclosure relates to systems and methods for creating empirical data from video observation of human behavior and movement information for input into an egress and movement analysis system, facilitating safety protocol and architectural design planning.

### BACKGROUND

It is known that a large number of users are typically present in places such as airports, stations, stadiums, shopping malls, concert venues, etc. With the growth of population and the gain in the popularity of such places, the number of users present and moving through these places has considerably increased over the years. For example, with the growth of population and the aviation industry, the number of users using the airports has exponentially increased over the past few decades.

It is important that the locations and dimensions of entry and exit points associated with such places are optimally planned, so that the users are able to conveniently enter and exit these places, with minimal probability of crowding. It is also important that safety and evacuation protocols for such places are carefully planned, so that the probability of mishaps during any emergency (e.g., fire, man-made emergency, etc.) is minimized.

Therefore, a system and method is required that may assist operators or management entities associated with such places to optimally design architecture and safety protocols.

### BRIEF DESCRIPTION OF THE DRAWINGS

The detailed description is set forth with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 depicts an environment in which techniques and structures for providing the systems and methods disclosed herein may be implemented.

FIG. 2 depicts a first view of an area of interest in a geographical area in accordance with the present disclosure.

FIG. 3 depicts a second view of an area of interest in a geographical area in accordance with the present disclosure.

FIG. 4 depicts a third view of an area of interest in a geographical area in accordance with the present disclosure.

FIG. 5 depicts a view of a plurality of users exiting an area via an exit point in accordance with the present disclosure.

FIG. 6 depicts a flow diagram of an example method for facilitating safety protocol and architectural design planning in accordance with the present disclosure.

### DETAILED DESCRIPTION

### Overview

The present disclosure describes a system and method for facilitating preparation of robust safety protocols and/or architectural designs of entry/exit points of geographical areas where a large number of users typically visit. Examples of such geographical areas include airports, stadiums, stations, concert venues, shopping malls, and/or the like.

In some aspects, the system may include a camera and a processor. The camera may be configured to capture images or videos of an area of interest in a geographical area. The area of interest may be, for example, an area in proximity to an entry or exit point of the geographical area or an area that is typically more prone to getting crowded. The processor may be configured to execute one or more image processing algorithms on the images captured by the camera, and determine a plurality of parameters associated with the area of interest based on the captured images. The processor may then transmit the parameters to an external device/server, which may be managed by a firm responsible for performing emergency evacuation analysis, fire inspection analysis, architecture planning, building safety analysis, and/or the like for the geographical area based on the obtained parameters.

In an exemplary aspect, the parameters may include, but are not limited to, a count of users in the area of interest, a shoulder width, or an elbow width, or a total width via a cylinder width of each user in the area of interest, a movement speed of each user in the area of interest, a density of users in the area of interest, a body roll factor/percentage of one or more users as the one or more users exit the area of interest via an exit point/door (or other thresholds of interest), types of mobility aids used by one or more users who are mobility impaired in the area of interest, types of bags carried by one or more users in the area of interest, and/or the like.

The processor may be further configured to determine, based on the captured images, that a distance of a user from an adjacent user is less than a predefined threshold. Responsive to such determination, the processor may determine a characteristic of relatability between the two users indicating whether the two users are in a relationship (e.g., a familial relationship) with each other, or just part of crowd. The processor may then transmit information associated with the characteristic of relatability to the server, so that the firm may accordingly plan an evacuation operation in the event of an emergency. As an example, if the two users are in relationship with each other, the users may prefer to move or exit together in the event of an emergency, and hence the firm may accordingly plan their evacuation.

In some aspects, the processor may determine, based on the captured images, that the two users may be in relationship with each other when the users may be wearing similar clothes, holding hands, carrying similar luggage, at least one user is a child, and/or the like.

The processor may be further configured to automatically identify an “optimal” area of interest in the geographical area based on a plurality of historical images associated with the geographical area, and transmit a command signal to the camera to adjust the camera alignment such that the camera captures images of the identified area of interest. Stated another way, in this case, the processor may automatically adjust the camera alignment such that the identified area of interest is in the camera's field of view (FOV). In alternative aspects, the processor may not be configured to automatically adjust the camera's alignment, but may instead automatically “identify” the optimal area(s) of interest in the images/livestream video feed of the geographical area captured and provided by the camera (or uploaded to the system by the firm), and may determine the parameters described above for the optimal area of interest. Stated another way, in this case, the processor may automatically focus on the “most important area” (i.e., the optimal area of interest) in the images/livestream video feed provided by camera, and perform pixel-level image processing on the most important area of the images/video to determine the parameters described above.

The present disclosure discloses a system and method that determines highly accurate and real-time user data associated with a plurality of areas of interest in a geographical area, so that optimal safety protocols and/or architectural designs of exit points/doors can be prepared. The system is further configured to automatically adjust the camera alignment, so that the cameras capture images of optimal areas of interest in the geographical area.

These and other advantages of the present disclosure are provided in detail herein.

### Illustrative Embodiments

The disclosure will be described more fully hereinafter with reference to the accompanying drawings, in which example embodiments of the disclosure are shown, and not intended to be limiting.

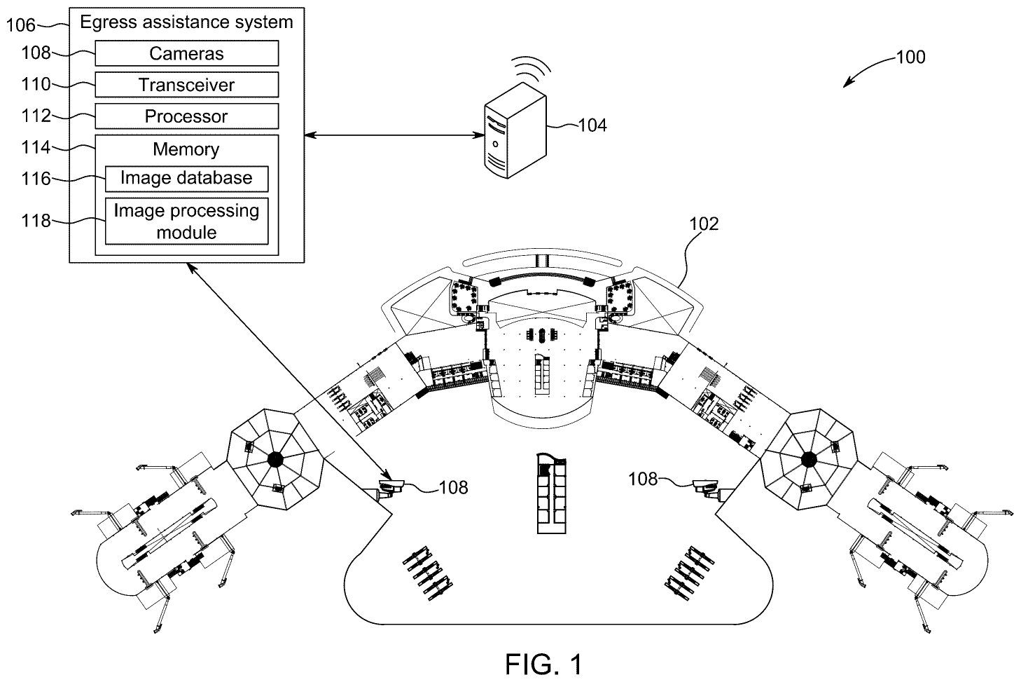

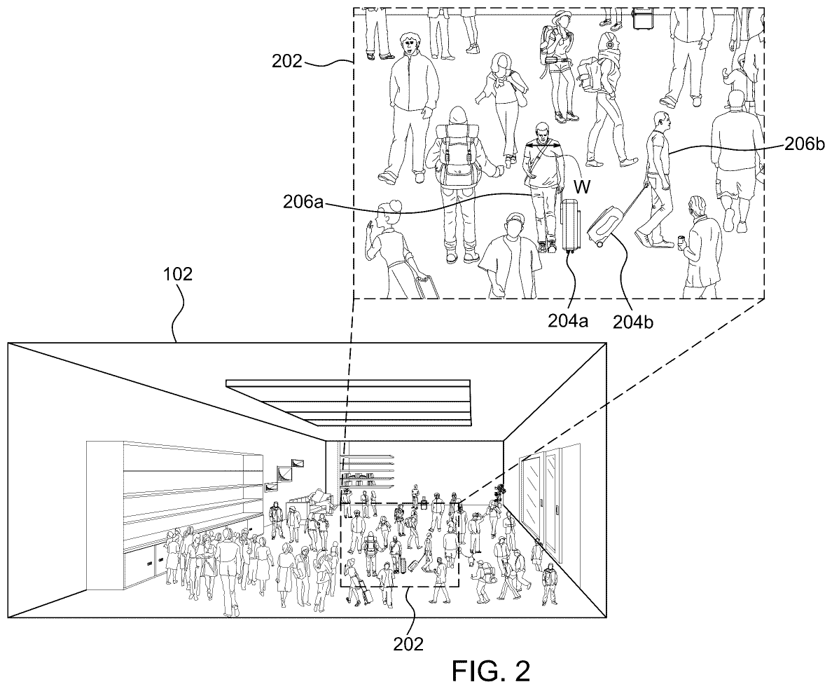

FIG. 1 depicts an environment 100 in which techniques and structures for providing the systems and methods disclosed herein may be implemented. FIG. 1 will be described in conjunction with FIGS. 2-5.

The environment 100 may include a geographical area 102, which may be, for example, an airport, a station, a shopping mall, a stadium, a concert venue, or any other similar area where a large count of users may be expected to be present at any given time. The geographical area 102 may include one or more entry and exit points (not shown in FIG. 1) through which a plurality of users may enter and exit the geographical area 102.

It may be appreciated that since the geographical area 102 hosts a large count of users, it is important that the locations and dimensions of the entry and exit points (e.g., doors) in the geographical area 102 are optimally designed/planned. For example, it is important that the entry and exit points are located optimally in the geographical area 102 so that the users may conveniently enter and exit the geographical area 102 via the entry/exit points, without causing significant crowding at any location in the geographical area 102. Further, the dimensions of each entry or exit point (e.g., door dimensions) should be based on an expected count of users that would typically enter or exit the geographical area 102 via the entry or exit point. For example, the door width should be wide when the expected count of users is high, so that crowding near the door may be prevented during normal operation or at usual user traffic at the geographical area 102.

Furthermore, since the geographical area 102 hosts a large count of users, it is important that safety protocols are properly planned and executed at the geographical area 102. For example, exit or egress protocols should be properly planned and executed at the geographical area 102, so that the users in the geographical area 102 may be safely evacuated in the event of an emergency (e.g., fire, or any other natural or man-made emergency). Moreover, the locations and/or dimensions of egress/exit points in the geographical area 102 should be aligned or designed according to the safety protocols.

To ensure effective planning and execution of safety protocols and architectural design for the geographical area 102, an operation and safety management firm/entity (“firm”) may be associated with the geographical area 102. The firm may be responsible for analyzing entry, egress and movement patterns of users associated with the geographical area 102 over a period of time, and prepare safety protocols, emergency evacuation plans, fire inspection plans, building safety plans, and/or architectural design for entry/exit points based on the analysis. The firm may be associated with an egress and movement analysis system/server 104 (or server 104), which may be configured to receive/ingest user pattern data/information associated with the geographical area 102, and prepare safety protocols/plans and architectural design based on the received data.

The environment 100 may further include an egress assistance system 106 (or system 106) that may be configured to determine the user pattern data/information associated with the geographical area 102, and transmit (transmit directly or store in a memory/solid state drive) the determined data/information to the server 104 so that the firm may efficiently prepare/plan safety protocols and architectural design for entry/exit points, as described above. The system 106 may be communicatively coupled with the server 104 via one or more networks. The network(s), as described here, illustrates an example communication infrastructure in which the connected devices discussed in various embodiments of this disclosure may communicate. The network(s) may be and/or include the Internet, a private network, public network or other configuration that operates using any one or more known communication protocols such as transmission control protocol/Internet protocol (TCP/IP), Bluetooth®, Bluetooth® Low Energy (BLE), Wi-Fi based on the Institute of Electrical and Electronics Engineers (IEEE) standard 802.11, ultra-wideband (UWB), and cellular technologies such as Time Division Multiple Access (TDMA), Code Division Multiple Access (CDMA), High-Speed Packet Access (HSPDA), Long-Term Evolution (LTE), Global System for Mobile Communications (GSM), and Fifth Generation (5G), to name a few examples.

The system 106 may include a plurality of units/components including, but not limited to, a plurality of cameras 108, a transceiver 110, a processor 112 and a memory 114. In some aspects, the cameras 108 may be part of the system 106. In alternative aspects, the cameras 108 may not be part of the system 106, and may instead be associated with or owned by the firm described above. The plurality of cameras 108 may be installed at a plurality of different locations in the geographical area 102. In some aspects, the plurality of cameras 108 may be installed at those locations in the geographical area 102 that may be in proximity to the entry and/or exit points of the geographical area 102, so that the cameras 108 may effectively capture static images or dynamic videos of users entering or exiting the geographical area 102 via the entry or exit points. In additional aspects, the plurality of cameras 108 may be installed at those locations in the geographical area 102 that may be “prone” to crowding, e.g., near a baggage carousel at an airport, concourse of a stadium, near an escalator in a mall, station, airport, and/or the like. Such locations are collectively referred to as “area of interest” in the present disclosure. Consequently, the plurality of cameras 108 is configured to capture static images or dynamic videos of the areas of interest in the geographical area 102. An example area of interest 202 in the geographical area 102 is depicted in FIG. 2.

The transceiver 110 may be configured to receive data/information/signals from the system 106 components and/or external systems, e.g., the server 104. For example, the transceiver 110 may be configured to receive the images captured by each camera 108 (directly from the cameras 108 or uploaded to the system 106 by the firm described above). Further, the transceiver 110 may be configured to transmit data/information/signals to the system 106 components and/or the external systems. For example, the transceiver 110 may transmit command signals to one or more cameras 108 to adjust the camera alignment. As another example, the transceiver 110 may transmit the images/videos captured by the cameras 108 to the server 104. If the images/videos captured by the cameras 108 are provided/uploaded by the firm, the transceiver 110 may not transmit the images/videos to the server 104.

The processor 112 may utilize the memory 114 to store programs in code and/or to store data for performing aspects in accordance with the disclosure. The memory 114 may be a non-transitory computer-readable storage medium or memory storing a program code that enables the processor 112 to perform operations in accordance with the present disclosure. The memory 114 may include any one or a combination of volatile memory elements (e.g., dynamic random-access memory (DRAM), synchronous dynamic random-access memory (SDRAM), etc.) and may include any one or more nonvolatile memory elements (e.g., erasable programmable read-only memory (EPROM), flash memory, electronically erasable programmable read-only memory (EEPROM), programmable read-only memory (PROM), etc.).

In some aspects, the memory 114 may include an image database 116 and an image processing module 118. The image database 116 may be configured to store the images/videos captured by the cameras 108. The image processing module 118 may be stored in the form of computer-executable instructions, and the processor 112 may be configured and/or programmed to execute the stored computer-executable instructions for performing functions/operations in accordance with the present disclosure. The function of the image processing module 118 is described later in the description below.

In operation, the camera 108 may capture a plurality of images associated with the area of interest 202 over a predefined time duration (e.g., over 1 hour, 3 hours, 6 hours, 12 hours, 24 hours, etc.). The camera 108 may transmit (directly or uploaded by the firm) the captured images to the transceiver 110, which may transmit the images to the image database 116 for storage purpose and/or to the processor 112 for processing (via the image processing module 118).

The processor 112 may obtain the captured images associated with the area of interest 202 from the image database 116 or directly from the transceiver 110. Responsive to obtaining the images, the processor 112 may execute the instructions stored in the image processing module 118, to execute one or more image processing algorithms (that may be part of the image processing module 118) on the images. In some aspects, the processor 112 may perform pixel-level image processing on the images by using the image processing algorithms, to determine a plurality of parameters in real-time associated with the area of interest 202 based on the captured images. The plurality of parameters may be, for example, an average count of a plurality of users in the area of interest 202 based on the images or a real-time count of users in the area of interest 202 based on an image, a body width “W” (as shown in FIG. 2, or an elbow or shoulder width) of each user in the area of interest 202, a movement speed/velocity of each user in the area of interest 202, density of users in the area of interest 202 (e.g., minimum density, maximum density, median density, mean density, mode density, etc. over time in the area of interest 202), and/or the like. Responsive to determining the parameters, the processor 112 may transmit, via the transceiver 110, information associated with the parameters to the server 104 and hence to the firm that may be managing the safety protocols of the geographical area 102 and/or planning architectural design changes in the geographical area 102.

A person ordinarily skilled in the art may appreciate that the parameters described above are highly beneficial and important for the firm managing the safety protocols of the geographical area 102 to know in real-time, to effectively plan evacuation of users from the geographical area 102 in the event of an emergency. For example, it is important for the firm to know an average and/or a real-time count of users near each exit point (which may be an area of interest, as an example), so that the firm can effectively evacuate the users in the event of an emergency. Further, if, based on the parameters, the firm realizes that a particular exit point is more crowded than the other exit points in the geographical area 102, the firm may divert the users to the “less-crowded” exit points to effectively execute the evacuation operation. Furthermore, the parameters such as the shoulder/elbow/cylinder width “W” of each user, the movement speed, etc. may assist the firm to effectively distribute the users amongst the different exit points of the geographical area 102 in the event of an emergency. For example, “broad-shouldered” users may be equally distributed amongst exit points, so that no exit point is crowded. In addition, slow moving users (e.g., old users or users with children) may be provided assistance during the evacuation operation.

It may be appreciated that knowing such parameters in real-time is highly important to safely and effectively evacuate the users from the geographical area 102 via the exit points. Since the flow of users through the areas of interest (e.g., the area of interest 202) may be dynamic, and may change very quickly (e.g., every second, minute, etc.), it may not be possible for a human to determine the parameters described above in real-time. Therefore, the processor 112 utilizes the image processing module 118 to execute the image processing algorithms on the captured images, so that the parameters described above may be determined quickly and in real-time (even if the parameters are changing quickly/dynamically).

Importance of identifying the parameters described above (and one or more additional parameters described later below) is described in the paper “People Movement Study Of Large Airport Data Generation, Flow Dynamics And Coupled Analysis” by Simon Goodhead, et al (Proceedings of the 6th International Symposium on Human Behavior in Fire 2015; Interscience Communications Limited, London, UK. September 2015). The paper is incorporated by reference in its entirety in the present disclosure.

The parameters described above are also useful in architectural design and planning. For example, if the firm determines, based on the parameters described above captured over a period of a long time duration (e.g., over 3-6 months), that a specific exit point is usually more crowded than other exit points in the geographical area 102, the firm may plan to increase the dimensions (e.g., width) of the specific exit point. This may help in reducing the amount of crowding at the exit point. Such data may also be used by the firm to distribute the regular user flow at the specific exit point to other exit points, so that all the exit points in the geographical area 102 may have a similar flow or count of users during most times of operation.

In some aspects, the processor 112 may determine further parameters associated with the area of interest 202 based on the images captured by the camera 108, and transmit the information associated with such parameters to the server 104/firm described above. For example, the processor 112 may determine one or more encumbrances or items 204a, 204b carried by one or more users 206a, 206b in the area of interest 202, and also determine the associated item types. For example, as shown in FIG. 2, the items 204a, 204b may be bags (or trolleys). The processor 112 may be configured to determine, based on the captured images, that the users 206a, 206b are carrying bags, and also determine the types of bags (e.g., suitcases, trolleys, duffel bags, backpack, etc.) the users 206a, 206b are carrying. A person ordinarily skilled in the art may appreciate that information associated with the users 206a, 206b carrying the items 204a, 24b and the associated item types may be highly beneficial for the firm described above to effectively prepare an evacuation plan in the event of any emergency. For example, the firm may identify such users in the geographical area 102, and determine that such users may find it difficult to move rapidly in the event of an emergency; therefore, the firm may provide additional assistance to such users while executing an evacuation operation. Examples of such additional assistance include, but are not limited to, changing the fire alarm detection and/or the fire alarm notification type, widening exits, etc.

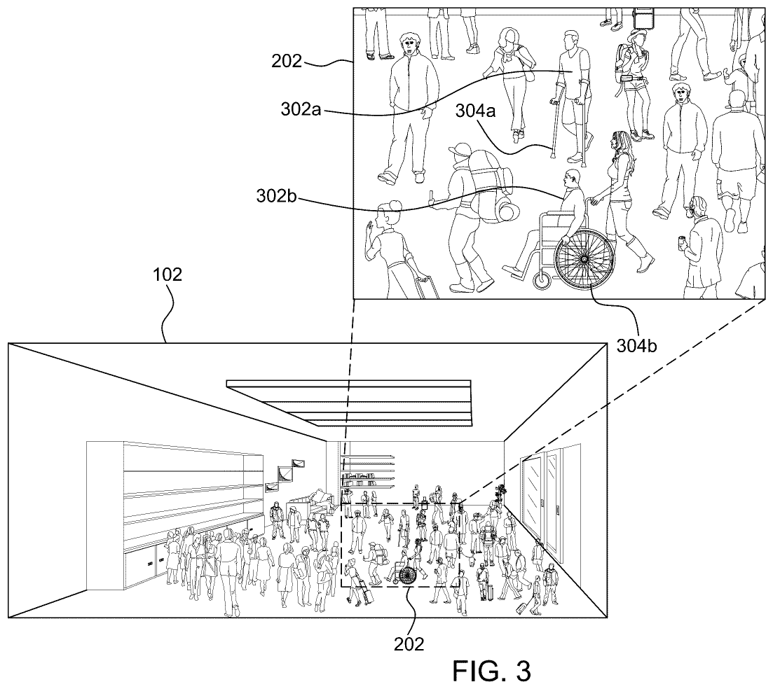

In further aspects, the processor 112 may determine additional parameters associated with the area of interest 202 based on the images captured by the camera 108. For example, the processor 112 may identify, based on the captured images, one or more users 302a, 302b in the area of interest 202 who may be mobility impaired (i.e., having difficulty in moving), as shown in FIG. 3. Responsive to identifying the users 302a, 302b in the area of interest 202, the processor 112 may determine, based on the captured images, types of mobility aids used by the users 302a, 302b to move in the area of interest 202. The types of mobility aids may be, for example, a cane 304a, a wheelchair 304b, a walker, a rollator, a power scooter, and/or the like. A person ordinarily skilled in the art may appreciate that information associated with the users 302a, 302b and the types of mobility aids used by such users may be highly beneficial for the firm described above to effectively prepare an evacuation plan in the event of any emergency. For example, the firm may identify such users in the geographical area 102, and determine that such users may require assistance during the evacuation operation. The firm may provide the appropriate assistance to such users in the event of an emergency.

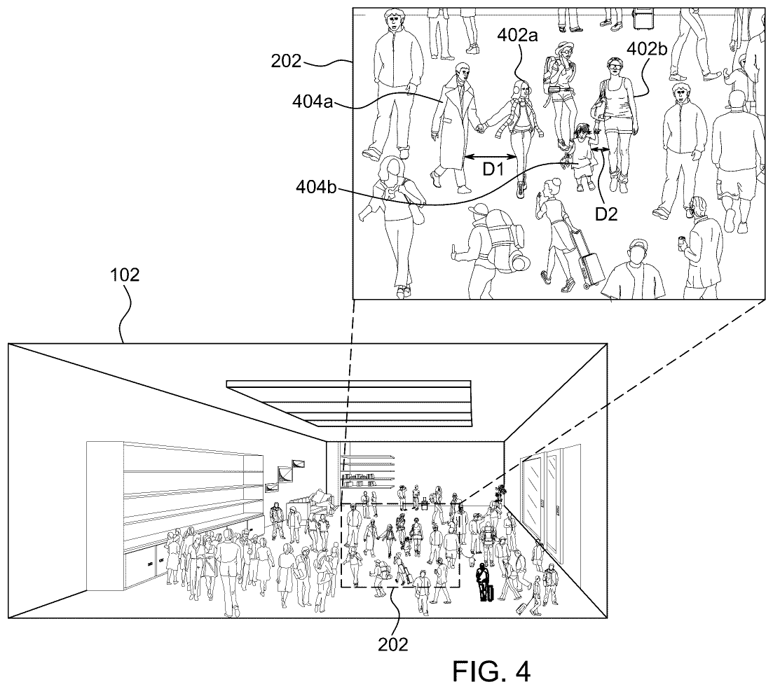

In additional aspects, the parameters determined by the processor 112 by using the images captured by the camera 108 may include a distance of each user, of a plurality of users, from adjacent users in the area of interest 202. For example, the processor 112 may determine, based on the captured images, distances “D1”, “D2” (or “comfort distances”, as shown in FIG. 4) of each user 402a, 402b from respective adjacent users 404a, 404b in the area of interest 202. Responsive to determining the distances “D1”, “D2”, the processor 112 may compare the distances “D1”, “D2” with a predefined threshold (e.g., 9 inches). When the distances “D1”, “D2” may be greater than the predefined threshold, the processor 112 may determine that the users in the area of interest 202 are moving at a “comfortable distance” away from each other, and hence there is no crowding in the area of interest 202.

On the other hand, responsive to determining that at least one distance “D1” or “D2” (or distance between any other two users in the area of interest 202) is less than the predefined threshold, the processor 112 may determine, based on the images captured by the camera 108, a characteristic of relatability between the users 402a, 402b and the users 404a, 404b. The characteristic of relatability may indicate, for example, whether the users 402a, 402b are in relationship with the respective adjacent users 404a, 40b, or the users 402a, 402b, 404a, 404b are just part of a crowd.

A person ordinarily skilled in the art may appreciate that if the users 402a, 402b are in relationship with the respective adjacent users 404a, 404b, the firm described above may determine that such users may be slower in moving in the event of an emergency, as such users would be moving in pairs or would be part of a larger group (e.g., a family of four present in the geographical area 102/airport). On the other hand, if the users 402a, 402b, 404a, 404b are just part of a crowd and not related to each other, such users may move at their observed speed in the event of an emergency, as such users are not “bound” to other users and hence may move independently. The firm may use the information/parameter described above to effectively plan the evacuation operation. For example, if the users 402a, 402b are in relationship with the respective adjacent users 404a, 404b, the firm may plan to divert/move such users together through exit points based on observed ratios of groups (e.g., based on a count of such users in each group) as such users would prefer to move together. The firm may also provide additional assistance to such users during the evacuation operation.

In some aspects, the processor 112 may determine that the users 402a, 402b are in relationship with the respective adjacent users 404a, 404b based on the images captured by the camera 108. As an example, the processor 112 may determine, based on the captured images, that the users 402a, 402b are in relationship with the respective users 404a, 404b when the users 402a, 404a and/or the users 402b, 404b are wearing similar clothes, are holding hands, are carrying similar luggage, and/or are walking with a similar gait and at an equivalent speed. The processor 112 may additionally determine that the user 402a (or the user 402b) may be in a relationship (or “familial relationship”) with the user 404a (or the user 404b) when at least one of the users 402a, 404a may be a child (as shown in FIG. 4).

The processor 112 may determine that the users 402a, 402b, 404a, 404b may just be part of a crowd when none of the criteria described above is met. Stated another way, the processor 112 may determine that the users 402a, 402b, 404a, 404b may just be part of a crowd when the users 402a, 402b may not be in relationship with the respective adjacent users 404a, 404b.

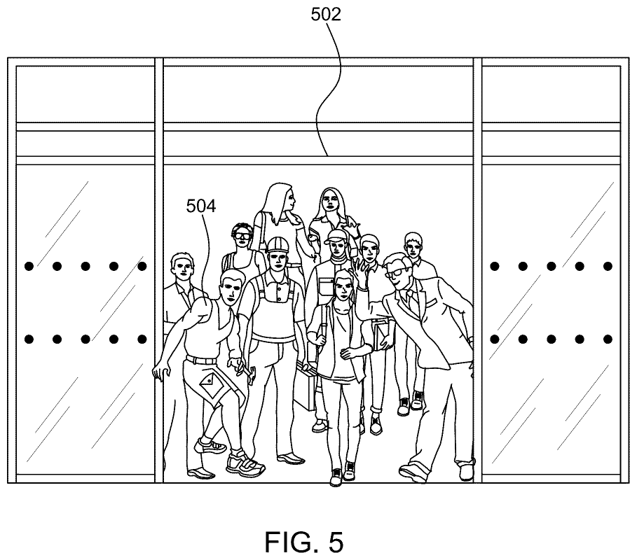

In further aspects, the processor 112 may be configured to determine/identify, based on the images captured by the camera 108, a presence of an exit point/door 502 in the area of interest 202 (as shown in FIG. 5). Responsive to identifying the presence of the door 502 in the area of interest 202, the processor 112 may determine additional parameters associated with the area of interest 202 and/or the users present in the area of interest 202. For example, the processor 112 may determine, based on the captured images, a flow rate of users exiting the area of interest 202 through the door 502. A person ordinarily skilled in the art may appreciate such information over long time duration (e.g., over 3-6 months) may facilitate the firm described above to plan adjustment of the door architectural design. For example, if the flow rate associated with the door 502 is usually low as compared to other exit points in the geographical area 102, the firm may plan to increase the dimensions (e.g., the width) associated with the door 502. The firm may additionally plan to divert users to other exit points (if possible) in this case.

As an additional parameter, the processor 112 may determine a body width roll percentage or a “body reduction factor” for one or more users 504 as the users 504 exit the area of interest 202 via the door 502. In some aspects, the body width roll percentage may be defined as a body width turn in a factor or a percentage reduction in the user's width that the user 504 is willing to undergo while moving through a door component or exiting through a crowded door. For example, if the user's body width is 30 inches, and the user 504 substantially turns the user's body towards front or back to make the user's effective width to be 21 inches while exiting the door 502, the processor 112 may determine that the user's body roll factor or percentage is 0.7 or 70%. Such a user may be more willing to “adjust” and accommodate other users when the door 502 may be crowded. On the other hand, if the user's body width is 30 inches, and the user 504 does not turn the user's body towards front or back while exiting the door 502 even when the door 502 is crowded, the processor 112 may determine that the user's body roll percentage is 0%. Such a user may be less willing to “adjust” and accommodate other users when the door 502 may be crowded.

The firm described above may use the information associated with the body roll percentage to effectively plan the evacuation operation in the event of an emergency. For example, if most of the users present in the area of interest 202 have a high body roll percentage value, it may indicate that the users in the area of interest 202 are “accommodating” and hence may exit the door 502 relatively conveniently in the event of an emergency. On the other hand, if most of the users present in the area of interest 202 have a low or zero body roll percentage value, it may indicate that the users in the area of interest 202 are less accommodating and hence the firm may have to divert or distribute such users to other exit points in the geographical area 102 in the event of an emergency.

The processor 112 may perform one or more additional operations to assist the firm described above in planning and implementing the safety protocols and/or facilitating in making/adjusting the architectural designs associated with the entry/exit points of the geographical area 102. For example, the processor 112 may be configured to determine a recommended position of an exit point or door in the geographical area 102 and/or a recommended exit point/door dimension based on the plurality of parameters and the information associated with the characteristic of relatability described above, determined over a long period of time (6 months or 9 months). In this case, the memory 114 may pre-store an existing architectural design of the geographical area 102, and the processor 112 may correlate the existing architectural design with the plurality of parameters and the information associated with the characteristic of relatability determined over a long period of time, to determine a recommended exit point position in the geographical area 102 and/or a recommended adjustment to an existing exit point dimension.

For example, if the processor 112 determines that the door 502 associated with the area of interest 202 is always (or mostly) crowded with a high user flow rate, the processor 112 may recommend to increase the door width by 20%. The percentage increase of door width may be based on the average user flow rate over the long period of time described above. The processor 112 may additionally recommend adding another door/exit point in proximity to the door 502 when the parameters described above indicates that the area of interest 202 is mostly crowded over the long period of time described above.

The processor 112 may transmit, via the transceiver 110, information associated with the recommended exit point position, the recommended exit point dimensions, the plurality of parameters described above, the characteristic of relatability between users, the images captured by the cameras 108, and/or the like to the server 104/firm at a predefined frequency or in real-time, so that the firm managing the server 104/geographical area 102 may effectively plan, as described above. As an example, the firm may perform Available Safe Egress Time (ASET) calculations in real-time based on the information obtained from the processor 112.

A person ordinarily skilled in the art may appreciate from the description above that the system 106/processor 112 is able to automatically characterize multiple individuals/users present in the areas of interest in the geographical area 102 simultaneously, regardless of the speed of movement of the users. Further, the system 106 automatically characterizes multiple individuals/users over large numbers (e.g., 100s at a time, if this large group is present within the area of interest 202). If a human were to do this, by the time the human may analyze the real-time video/images captured by the cameras 108, the individuals/users in the scene would have already changed, and hence the data would become inaccurate. The system 106/processor 112 characterizes the users, identifies the total count of users, and the density in real-time and constantly monitors that, so that no data is ever missed and the analysis by the firm is made on highly accurate and real-time data.

The processor 112 may further perform additional actions to accurately identify/capture the most useful area in the geographical area 102. For example, the processor 112 may analyze (via the image processing module 118) a plurality of historical and/or real-time images associated with the geographical area 102 that may be stored in the image database 116, and automatically determine optimal areas of interest (e.g., the area of interest 202 described above) in the geographical area 102 based on the image analysis. The optimal areas of interest may be those areas in the geographical area 102 that may be close to or in proximity to the entry or exit points or areas that are more prone to crowding, identified based on the plurality of historical and/or real-time images associated with the geographical area 102.

Responsive to identifying the optimal areas of interest, the processor 112 may transmit, via the transceiver 110, command signals to the cameras 108 to adjust a camera alignment of each camera 108 such the determined optimal areas of interest are within the cameras'field of view (FOV). For example, the processor 112 may transmit the command signals to rotate left or right, or move up or down each camera 108, such that the determined optimal area of interest is within the camera's FOV. In this manner, the processor 112 automatically “aligns” each camera 108 to an optimal area in the geographical area 102, which may produce the most useful information/parameters for the firm described above or the server 104.

In alternative aspects, the processor 112 may not be configured to automatically adjust the camera's alignment as described above, but may instead automatically “identify” the optimal area of interest in the images/livestream video feed of the geographical area 102 captured and provided by the cameras 108 (or uploaded by the firm to the system 106), and may determine the parameters described above for the optimal area of interest. Stated another way, in this case, the processor 112 may automatically focus on the “most important area” (i.e., the optimal area of interest) in the images/livestream video feed provided by cameras 108, and perform pixel-level image processing on the most important area of the images/video to determine the parameters described above.

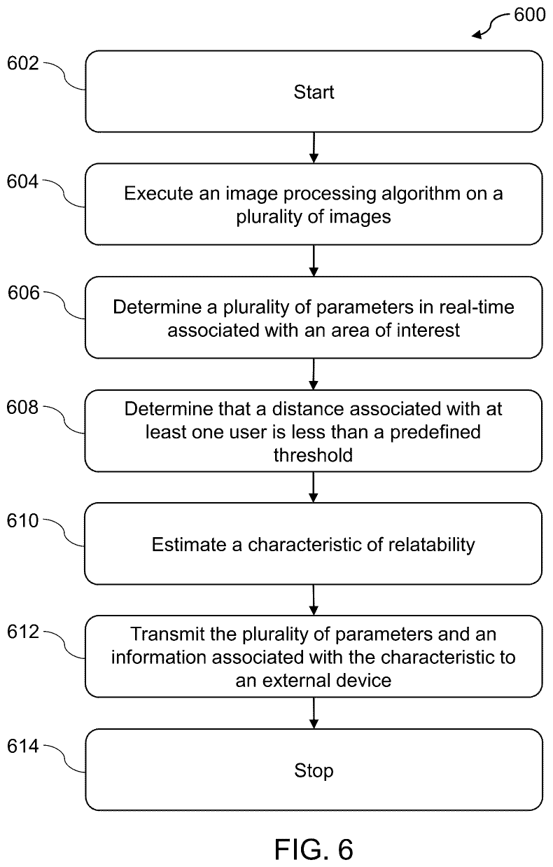

FIG. 6 depicts a flow diagram of an example method 600 for facilitating safety protocol and architectural design planning in accordance with the present disclosure. FIG. 6 may be described with continued reference to prior figures. The following process is exemplary and not confined to the steps described hereafter. Moreover, alternative embodiments may include more or less steps than are shown or described herein and may include these steps in a different order than the order described in the following example embodiments.

The method 600 starts at step 602. At step 604, the method 600 may include executing, by the processor 112, an image processing algorithm on the plurality of images of the area of interest 202 captured by the camera 108. At step 606, the method 600 may include determining, by the processor 112, the plurality of parameters in real-time associated with the area of interest 202 based on the plurality of images, responsive to executing the image processing algorithm. The examples of the plurality of parameters are described above. In an exemplary aspect, the parameter may be the distance “D1” between the users 402a and 404a.

At step 608, the method 600 may include determining, by the processor 112, that the distance “D1” is less than a predefined threshold. At step 610, the method 600 may include estimating, by the processor 112 and based on the plurality of images, a characteristic of relatability between the users 402a and 404a responsive to determining that the distance “D1” is less than the predefined threshold. As described above, the characteristic of relatability may indicate whether the users 402a and 404a are in a relationship with each other, or are just part of crowd.

At step 612, the method 600 may include transmitting, by the processor 112, the plurality of parameters and an information associated with the characteristic of relatability to the server 104. At step 614, the method 600 may stop.

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a feature, structure, or characteristic is described in connection with an embodiment, one skilled in the art will recognize such feature, structure, or characteristic in connection with other embodiments whether or not explicitly described.

Further, where appropriate, the functions described herein can be performed in one or more of hardware, software, firmware, digital components, or analog components. For example, one or more application specific integrated circuits (ASICs) can be programmed to carry out one or more of the systems and procedures described herein. Certain terms are used throughout the description and claims refer to particular system components. As one skilled in the art will appreciate, components may be referred to by different names. This document does not intend to distinguish between components that differ in name, but not function.

It should also be understood that the word “example” as used herein is intended to be non-exclusionary and non-limiting in nature. More particularly, the word “example” as used herein indicates one among several examples, and it should be understood that no undue emphasis or preference is being directed to the particular example being described.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Computing devices may include computer-executable instructions, where the instructions may be executable by one or more computing devices such as those listed above and stored on a computer-readable medium.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating various embodiments and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

That which is claimed is:

1. A system comprising:
a processor configured to:
execute an image processing algorithm on a plurality of images of an area of interest in a geographical area captured by a camera;
determine a plurality of parameters in real-time associated with the area of interest based on the plurality of images, responsive to executing the image processing algorithm, wherein the plurality of parameters comprises a distance of each user, of a plurality of users, from adjacent users in the area of interest;
determine that the distance associated with at least one user, of the plurality of users, is less than a predefined threshold;
estimate, based on the plurality of images, a characteristic of relatability between the at least one user and an adjacent user responsive to determining that the distance associated with the at least one user is less than the predefined threshold, wherein the characteristic is one of:
the at least one user being in a relationship with the adjacent user, or
the at least one user being part of a crowd; and
transmit the plurality of parameters and an information associated with the characteristic to an external device.

2. The system of claim 1, wherein the processor estimates that the at least one user is in a relationship with the adjacent user when the processor determines, based on the plurality of images, that:
the at least one user and the adjacent user are wearing similar clothes,
the at least one user and the adjacent user are holding hands,
at least one of the at least one user and the adjacent user is a child,
the at least one user and the adjacent user are carrying similar luggage, or
the at least one user and the adjacent user are walking with a similar gait and at an equivalent speed.

3. The system of claim 2, wherein the processor estimates that the at least one user is part of a crowd when the processor determines that the at least one user is not in a relationship with the adjacent user.

4. The system of claim 1, wherein the plurality of parameters further comprises at least one of: a count of users in the area of interest, a shoulder width, an elbow width, a cylinder width of each user in the area of interest, or a movement speed of each user in the area of interest.

5. The system of claim 1, wherein the processor is further configured to determine, based on the plurality of images, a presence of an exit point in the area of interest.

6. The system of claim 5, wherein the plurality of parameters further comprises a body roll factor/percentage of one or more users as the one or more users exit the area of interest via the exit point.

7. The system of claim 5, wherein the plurality of parameters further comprises a flow rate of users from the exit point.

8. The system of claim 1, wherein the plurality of parameters further comprises a density of users in the area of interest.

9. The system of claim 1, wherein the processor is further configured to identity, based on the plurality of images, an item carried by one or more users in the area of interest and an associated item type, and wherein the plurality of parameters further comprises an information associated with the item and the associated item type.

10. The system of claim 9, wherein the item is a bag or a trolley.

11. The system of claim 1, wherein the processor is further configured to:
identify, based on the plurality of images, that one or more users are mobility impaired in the area of interest; and
determine a type of mobility aid used by the one or more users to move in the area of interest, responsive to identifying that the one or more users are mobility impaired,
wherein the plurality of parameters further comprises an information associated with the type of mobility aid.

12. The system of claim 11, wherein the type of mobility aid comprises at least one of: a wheelchair, a cane, a walker, a rollator, or a power scooter.

13. The system of claim 1, wherein the processor is further configured to:
determine at least one of a recommended position of an exit point in the geographical area or a recommended exit point dimension based on the plurality of parameters and the information associated with the characteristic; and
transmit an information associated with the recommended position or the recommended exit point dimension to the external device.

14. A method comprising:
executing, by a processor, an image processing algorithm on a plurality of images of an area of interest in a geographical area captured by a camera;
determining, by the processor, a plurality of parameters in real-time associated with the area of interest based on the plurality of images, responsive to executing the image processing algorithm, wherein the plurality of parameters comprises a distance of each user, of a plurality of users, from adjacent users in the area of interest;
determining, by the processor, that the distance associated with at least one user, of the plurality of users, is less than a predefined threshold;
estimating, by the processor and based on the plurality of images, a characteristic of relatability between the at least one user and an adjacent user responsive to determining that the distance associated with the at least one user is less than the predefined threshold, wherein the characteristic is one of:
the at least one user being in a relationship with the adjacent user, or
the at least one user being part of a crowd; and
transmitting, by the processor, the plurality of parameters and an information associated with the characteristic to an external device.

15. The method of claim 14, wherein estimating that the at least one user is in a relationship with the adjacent user comprises determining, based on the plurality of images, that:
the at least one user and the adjacent user are wearing similar clothes,
the at least one user and the adjacent user are holding hands,
at least one of the at least one user and the adjacent user is a child,
the at least one user and the adjacent user are carrying similar luggage, or
the at least one user and the adjacent user are walking with a similar gait and at an equivalent speed.

16. The method of claim 14 further comprising:
identifying, based on the plurality of images, that one or more users are mobility impaired in the area of interest; and
determining a type of mobility aid used by the one or more users to move in the area of interest, responsive to identifying that the one or more users are mobility impaired,
wherein the plurality of parameters further comprises an information associated with the type of mobility aid.

17. The method of claim 14, wherein the plurality of parameters further comprises at least one of: a count of users in the area of interest, a shoulder width, an elbow width, a cylinder width of each user in the area of interest, or a movement speed of each user in the area of interest.

18. The method of claim 14 further comprising determining, based on the plurality of images, a presence of an exit point in the area of interest.

19. The method of claim 18, wherein the plurality of parameters further comprises a body roll factor/percentage of one or more users as the one or more users exit the area of interest via the exit point.

20. A non-transitory computer-readable storage medium having instructions stored thereupon which, when executed by a processor, cause the processor to:
execute an image processing algorithm on a plurality of images of an area of interest in a geographical area captured by a camera;
determine a plurality of parameters in real-time associated with the area of interest based on the plurality of images, responsive to executing the image processing algorithm, wherein the plurality of parameters comprises a distance of each user, of a plurality of users, from adjacent users in the area of interest;
determine that the distance associated with at least one user, of the plurality of users, is less than a predefined threshold;
estimate, based on the plurality of images, a characteristic of relatability between the at least one user and an adjacent user responsive to determining that the distance associated with the at least one user is less than the predefined threshold, wherein the characteristic is one of:
the at least one user being in a relationship with the adjacent user, or
the at least one user being part of a crowd; and
transmit the plurality of parameters and an information associated with the characteristic to an external device.
